(19) United States
(12) Patent Application Publication
(10) Pub. No.: US 2009/0183906 A1
(43) Pub. Date: Jul. 23, 2009

(54) SUBSTRATE FOR MOUNTING DEVICE AND METHOD FOR PRODUCING THE SAME, SEMICONDUCTOR MODULE AND METHOD FOR PRODUCING THE SAME, AND PORTABLE APPARATUS PROVIDED WITH THE SAME

(76) Inventors: Hajime KOBAYASHI, Kumagaya-shi (JP); Yasuyuki Yanase, Anpachi-gun (JP); Yoshio Okayama, Anpachi-gun (JP); Yasunori Inoue, Ogaki-shi (JP)

Correspondence Address: MCDERMOTT WILL & EMERY LLP, 600 13TH STREET, N.W., WASHINGTON, DC, 20005-3096, US

(21) Appl. No.: 12/345,170

(22) Filed: Dec. 29, 2008

(30) Foreign Application Priority Data
Dec. 27, 2007 (JP) 2007-337700

(51) Int. Cl. H05K 1/18; H05K 1/02

(52) U.S. Cl. 174/260; 174/261; 174/251; 257/E23.01

(57) ABSTRACT

A substrate for mounting a device includes: an insulating resin layer made of an insulating resin; a wiring layer provided on one major surface of the insulating resin layer; and a projected portion that projects toward the direction opposite to the insulating resin layer from the wiring layer, and that is used for supporting a low-melting metal ball, while being connected to the wiring layer electrically. The wiring layer and the projected portion are formed into one body.

### CROSS-REFERENCE TO RELATED APPLICATIONS

This application is based upon and claims the benefit of priority from the prior Japanese Patent Application No. 2007-337700, filed on Dec. 27, 2007, the entire contents of which are incorporated herein by reference.

### BACKGROUND OF THE INVENTION

1. Field of the Invention

The present invention relates to a substrate for mounting a device and a method for producing the same, a semiconductor module and a method for producing the same, and a portable apparatus provided with the same.

2. Description of the Related Art

In recent years, with miniaturization and high performance of electronic apparatuses, there is a demand for further miniaturization of semiconductor devices used for the electronic apparatuses. With miniaturization of semiconductor devices, it is essential to narrow the pitch between electrodes for being mounted on printed wiring boards. As a surface-mounting method of semiconductor devices, a flip-chip mounting method is known in which a solder bump is formed on an electrode of a semiconductor device, and the solder bump and an electrode pad of a printed wiring board are soldered. In addition, as structures adopting the flip-chip mounting method, the BGA (Ball Grid Array) structure and the CSP (Chip Size Package) structure are known.

With respect to these structures, a semiconductor device of which projected electrode formed on a semiconductor substrate is composed of a lower electrode and an upper electrode formed on the lower electrode, and a low-melting metal ball is formed on the lower and upper electrodes, respectively, is known. The semiconductor device is intended to increase the connection area between the projected electrode and the low-melting metal ball by adopting the structure stated above to enhance the connection strength between the two, thereby improving the connection reliability between them.

However, in the conventional structure stated above, the lower electrode and the upper electrode constituting the projected electrode are structured by separate bodies, and a wiring and the projected electrode are also structured by separate bodies; hence, when a thermal stress occurs, there is a fear that a crack possibly occurs in the connection portion between the lower electrode and the upper electrode or between the wiring and the projected electrode, resulting in the deteriorated connection reliability between a semiconductor device and a printed wiring board.

### SUMMARY OF THE INVENTION

The present invention has been made in view of these situations and a general purpose of the invention is to provide a technique in which the connection reliability between a semiconductor module and a printed wiring board is improved.

In order to solve the above-mentioned problem, an embodiment of the present invention is a substrate for mounting a device. The substrate for mounting a device comprises: an insulating resin layer; a wiring layer provided on one major surface of the insulating resin layer; and a projected portion that projects toward the direction opposite to the insulating resin layer from the wiring layer, and that is used for supporting a connection metal, while being connected to the wiring layer electrically, wherein the wiring layer and the projected portion are formed into one body.

According to the embodiment, because the wiring layer and the projected portion are formed into one body, the connection reliability between a semiconductor module and a printed wiring board is improved.

Other embodiment of the present invention is also a substrate for mounting a device. The substrate for mounting a device comprises: an insulating resin layer; a wiring layer formed on one major surface of the insulating resin layer; a projected portion that projects toward the direction opposite to the insulting resin layer from the wiring layer, while being connected to the wiring layer electrically; and a connection metal that is provided in a region of the wiring layer where the projected portion projects, wherein the wiring layer and the projected portion are formed into one body.

According to the embodiment, because the wiring layer and the projected portion are formed into one body, the connection reliability between a semiconductor module and a printed wiring board is improved.

In the above embodiment, the connection metal may cover the whole surface of the projected portion.

In the above embodiment, concavities and convexities may be formed on the surface (top face and/or side face) of the projected portion.

In the above embodiment, an average roughness (Rz) of 10 points of the concavities and the convexities may be within the range of 0.5 to 3.0 μm.

In the above embodiment, the wiring layer and the projected portion may be made of a rolled metal.

In the above embodiment, the side face of the projected portion may have a tapered shape with a progressively smaller diameter toward the top of the projected portion from the major surface of the wiring layer.

In the above embodiment, the substrate for mounting a device may further comprise a protective layer that has an opening portion formed in a region corresponding to the projected portion, and that is provided on the major surface of the wiring layer on the side where the projected portion projects such that the projected portion projects from the opening portion; and part of the connection metal may be engaged with the interior face of the opening portion.

In the above embodiment, the connection metal maybe formed on the top face of the projected portion.

Still another embodiment of the present invention is a semiconductor module. The semiconductor module comprises: the substrate for mounting a device according to any one of embodiments stated above; and a semiconductor device mounted on the substrate for mounting a device.

In the above embodiment, the substrate for mounting a device may have a projected electrode that is connected to the wiring layer electrically and projects toward the insulating resin layer side from the wiring layer, and the semiconductor device may have a device electrode facing the projected electrode; and the projected electrode penetrates the insulating resin layer to be connected to the device electrode electrically.

Still another embodiment of the present invention is a portable apparatus. The portable apparatus is mounted with the semiconductor module according to any one of the embodiments stated above.

Still another embodiment of the present invention is a method for producing a substrate for mounting a device. The method for producing a substrate for mounting a device comprises: stacking a metal plate on one major surface of an insulating resin layer; removing selectively the major surface of the metal plate on the opposite side to the insulting resin layer to form a projected portion for supporting a connection metal; and removing selectively the metal plate to form a wiring layer.

Still another embodiment of the present invention is also a method for producing a substrate for mounting a device. The method for producing a substrate for mounting a device comprises: stacking a metal plate on one major surface of an insulating resin layer; removing selectively the major surface of the metal plate on the opposite side to the insulating resin layer to form a projected portion; removing selectively the metal plate to form a wiring layer; and providing a connection metal in a region of the wiring layer where the projected portion is formed.

In the above embodiment, the method for producing a substrate for mounting a device may further comprise forming concavities and convexities on the surface (top face and/or side face) of the projected portion.

Still another embodiment of the present invention is a method for producing a semiconductor module. The method for producing a semiconductor module comprises: preparing a metal plate on one major surface of which a projected electrode projects; pressure-bonding the metal plate and a semiconductor device in which a device electrode corresponding to the projected electrode is provided, via an insulating resin layer, such that the projected electrode and the device electrode are connected electrically by the projected electrode penetrating through the insulating resin layer; removing selectively the other major surface of the metal plate to form a projected portion; removing selectively the metal plate to form a wiring layer; and providing a connection metal in a region of the wiring layer where the projected portion is formed.

### BRIEF DESCRIPTION OF THE DRAWINGS

FIG. 1 is a schematic cross-sectional diagram illustrating a structure of a substrate for mounting a device and a semiconductor module using the same according to Embodiment 1;

FIGS. 2A to 2D are cross-sectional diagrams illustrating a method for forming a projected electrode;

FIGS. 3A to 3F are cross-sectional diagrams illustrating a method for forming a wiring layer and a low-melting metal ball, and a method for connecting the projected electrode and a device electrode;

FIGS. 4A to 4F are diagrams illustrating a method for forming the wiring layer and the low-melting metal ball, and a method for connecting the projected electrode and the device electrode, according to Embodiment 2;

FIG. 5 is a diagram illustrating the structure of a portable phone according to Embodiment 3; and

FIG. 6 is a partial cross-sectional diagram of the portable phone.

### DETAILED DESCRIPTION OF THE INVENTION

The invention will now be described by reference to the preferred embodiments. This does not intend to limit the scope of the present invention, but to exemplify the invention.

Hereinafter, the present invention will now be described based on the preferred embodiments with reference to accompanying drawings. The same or like components, members, or processes illustrated in each drawing are denoted by the same reference numerals, and the duplicative descriptions will be appropriately omitted. The embodiments are not intended to limit the invention but to serve as particular examples thereof, and all features or combinations thereof described there are not always essential to the present invention.

### Embodiment 1

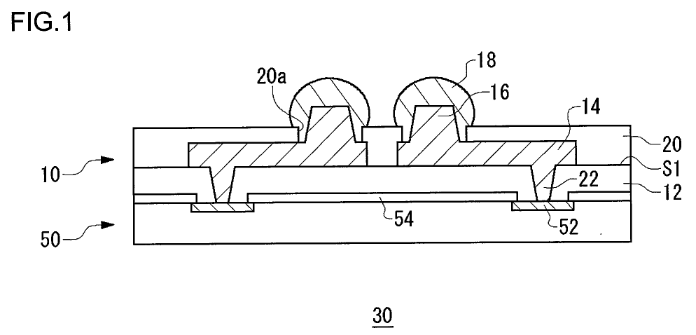

FIG. 1 is a schematic cross-sectional diagram illustrating a structure of a substrate 10 for mounting a device according to Embodiment 1 and a semiconductor module 30 using the same. The semiconductor module 30 comprises: the substrate 10 for mounting a device; and a semiconductor device 50 mounted thereon.

The substrate 10 for mounting a device comprises: an insulating resin layer 12 made of an insulating resin; a wiring layer 14 provided on one major surface S1 of the insulting resin layer 12; and a projected portion 16 that projects toward the direction opposite to the insulating resin layer from the wiring layer 14, while being connected to the wiring layer 14 electrically.

The insulating resin layer 12 is made of an insulting resin and formed with a material that induces a plastic flow when, for example, pressurized. An example of a material that induces a plastic flow when pressurized includes an epoxy-based thermosetting resin. As an epoxy-based thermosetting resin used in the insulating resin layer 12, a material may be used as far as the material has a viscosity property of, for example, 1 kpa·s under the condition of a temperature of 160° C. and a pressure of 8 Mpa. When pressurized with a pressure of, for example, 5 to 15 Mpa under the condition of a temperature of 160° C., the epoxy-based thermosetting resin reduces its viscosity to ⅛th-fold in comparison to that when not pressurized. On the other hand, the epoxy resin in the B-stage before thermosetting is less viscous in the same level as that when not pressurized, and not viscous even when pressurized, under the condition of the glass transition temperature Tg or less.

The wiring layer 14 is provided on one major surface S1 of the insulating resin layer 12, and is formed with a conductive material, preferably a rolled metal, further preferably a rolled copper. Alternatively, the wiring layer 14 may be formed with an electrolyte copper or the like. On the wiring layer 14, a plurality of projected portions 16 are formed into one body so as to project therefrom, on the opposite side to the insulating resin 12. Accordingly, the projected portions 16 are also made of the same conductive material as with the wiring layer 14, for example, a rolled metal. The positions where the projected portions 16 project are ones where the wirings are put around, for example, in rewiring.

The projected portion 16 is used for supporting a connection metal such as a low-melting metal ball (for example, a solder ball), which is used for being connected to a printed wiring board or the like electrically. When the low-melting metal ball 18 is provided in the region of the wiring layer 14 where the projected portion 16 projects, the whole surface of the projected portion 16 is covered by the low-melting metal ball 18 to create the situation where the low-melting metal ball 18 is supported by the projected portion 16. Therefore, the height (hereinafter, referred to as the “ball height”) from the major surface of the wiring layer 14 to the top of the low-melting metal ball 18 can be kept high.

The projected portion 16 has, for example, a rounded shape when seen in planar view, and the side face thereof has a tapered shape with a progressively smaller diameter toward the top of the projected portion 16 from the major surface of the wiring layer 14. Because the side face of the projected portion 16 has a tapered shape, the contact area between the projected portion 16 and the low-melting metal ball 18 is increased; hence the ball height can be kept high. The shape of the projected portion 16 is not particularly limited to, and, for example, a cylindrical shape having a certain diameter and a polygonal shape such as a quadrangle when seen in planar view are also possible. In addition, certain concavities and convexities may also be formed on the surface (top face and/or side face) of the projected portion 16. Herein, the certain concavities and convexities have a function that the connection strength between the projected portion 16 and the low-melting metal ball 18 can be increased by an anchor effect. The concavities and convexities have, for example, an average roughness (Rz) of 10 points within the range of 0.5 to 3.0 μm (inclusive). When Rz of the concavities and convexities is less than 0.5 μm, a desired anchor effect of increasing the connection strength between the projected portion 16 and the low-melting metal ball 18 cannot be obtained. When Rz of the concavities and convexities is more than 3.0 μm, the low-melting metal ball 18 cannot enter the inside of the concavities, resulting in a fear that a space between the low-melting metal ball 18 and the projected portion 16 is created. Due to this, the low-melting metal ball 18 is easy to peel from the projected portion 16 when a thermal stress occurs. Therefore, the concavities and convexities are preferably within the range stated above. Alternatively, the degree of the concavities and convexities may be determined by experiments.

In the present embodiment, the low-melting metal ball 18 is provided so as to cover the whole surface of the projected portion 16; however, the low-melting metal ball 18 is not particularly limited thereto but may be formed on the top face of the projected portion 16. Due to this, the ball height can also be kept high.

The top face and the side face of the projected portion 16, or only the top face thereof may be covered by a metal layer such as an Au/Ni plated layer formed by, for example, an electrolytic plating process or a non-electrolytic plating process. For example, when a rolled copper is used for the wiring layer 14 and the projected portion 16, and a solder ball is used as the low-melting metal ball 18, there is a fear that the projected portion 16 could become hollow because of the reaction between the copper (Cu) and the tin (Sn) in the solder. Also, there is a fear that a crack could occur in the interfacial surface between the copper and the tin. These phenomena can be prevented by covering the projected portion 16 with a metal layer.

A protective layer 20 for preventing oxidation of the wiring layer 14 or the like is provided on the major surface of the wiring layer 14 on the side where the projected portion 16 projects. An example of the protective layer 20 includes a solder resist layer or the like. An opening portion 20a is formed in a region of the protective layer 20 corresponding to the projected portion 16, and the protective layer 20 is provided such that the projected portion 16 projects from the opening portion 20a. Herein, part of the low-melting metal ball 18 is engaged with the interior side face of the opening portion 20a. That is, part of the low-melting metal ball 18 enters the concavities enclosed by the interior side face of the opening portion 20a of the protective layer 20, the side face of the projected portion 16, and the surface of the wiring layer 14. Due to this, the expansion of the low-melting metal ball 18 in the direction parallel to the major surface of the wiring layer 14 is prevented; hence, the ball height can be kept high.

Further, a projected electrode 22 that is connected to the wiring layer 14 electrically, and that projects toward the side of the insulating resin layer 12 from the wiring layer 14, may also be provided on the substrate 10 for mounting a device. The projected electrode 22 has a shape in which the whole shape of the electrode becomes thinner as approaching the tip thereof.

A semiconductor module 30 is formed by mounting a semiconductor device 50 on the substrate 10 for mounting a device having the structure stated above. The semiconductor module 30 according to the present embodiment has a structure in which the projected electrode 22 on the substrate 10 for mounting a device, and a device electrode 52 in the semiconductor device 50 are connected electrically via the insulating resin layer 12. The structure of the semiconductor module 30 is not particularly limited thereto, but the semiconductor device 50 may be implemented at any position on the substrate 10 for mounting a device by any process such as wire bonding.

The semiconductor device 50 has the device electrodes 52 corresponding to each of the projected electrodes 22. On the major surface of the semiconductor device 50 on the side where the device is in contact with the insulating resin layer 12, a device protective layer 54 is stacked such that the device electrode 52 is opened. Specific example of the semiconductor device 50 includes a semiconductor chip such as an integrated circuit (IC) and a large-scale IC (LSI) or the like. Specific example of the device protective layer 54 includes a polyimide layer. In addition, for example, aluminum (Al) is used for the device electrode 52.

In the present embodiment, the insulating resin layer 12 is provided between the substrate 10 for mounting a device and the semiconductor device 50, and the substrate 10 for mounting a device is pressure-bonded to one major surface S1 of the insulating resin layer 12, and the semiconductor device 50 is pressure-bonded to the other major surface thereof. The projected electrode 22 penetrates the insulating resin layer 12 to be connected electrically to the device electrode 52 provided in the semiconductor device 50. Because the insulating resin layer 12 is made of a material that induces a plastic flow when pressurized, the intervention of a residual layer of the insulating resin layer 12 between the projected electrode 22 and the device electrode 52, can be prevented in the state where the substrate 10 for mounting a device, the insulating resin layer 12, and the semiconductor device 50 are formed into one body in this order; hence the connection reliability can be improved.

(Method for Producing Substrate for Mounting Device and Semiconductor Module)

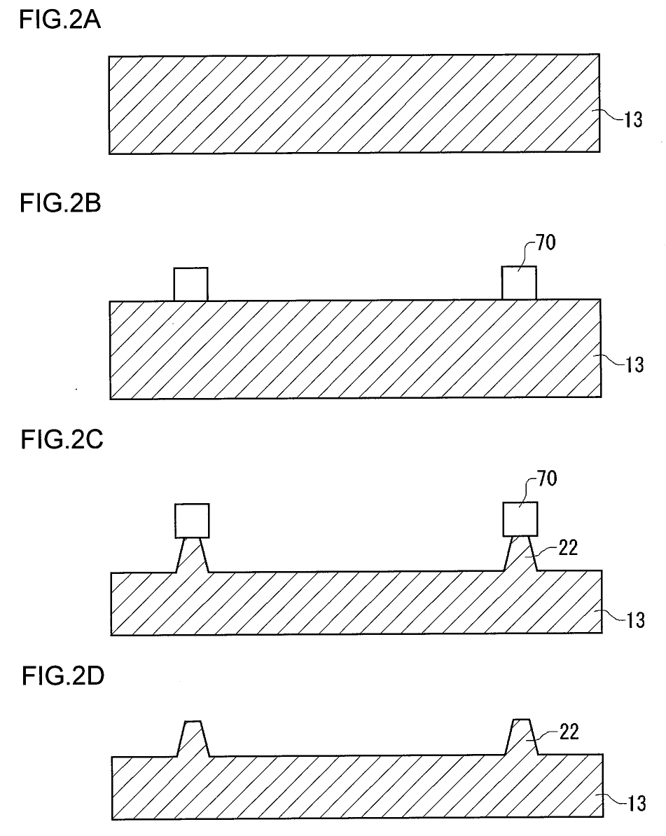

FIGS. 2A to 2D are cross-sectional diagrams illustrating a method for forming the projected electrode 22.

As illustrated in FIG. 2A, a copper plate 13 is prepared as a metal plate having a thickness that is larger than at least the total of the height of the projected portion 16, the height of the projected electrode 22, and the thickness of the wiring layer 14, those three being formed later.

As illustrated in FIG. 2B, resists 70 are subsequently formed selectively in accordance with the pattern of the projected electrodes 22 by the lithography method. Specifically, the resist 70 are formed selectively on the copper plate 13 in the following process: a resist film with a certain thickness is attached to the copper plate 13 by using a laminating apparatus, and exposed by using a photomask with the pattern of the projected electrodes 22; and the resist film is then developed. In order to improve the adhesion property with the resist, it is preferable that the surface of the copper plate 13 is subjected to a pretreatment such as grinding and washing or the like, before laminating the resist film, if needed.

As illustrated in FIG. 2C, a certain pattern of the projected electrodes 22 is then formed on the copper plate 13 by using the resist 70 as a mask. Specifically, the projected electrodes 70 with a certain pattern are formed by etching the copper plate 13 with the use of the resist 70 as a mask.

As illustrated in FIG. 2D, the resist 70 is subsequently peeled off using a parting agent. By the process stated above, the projected electrodes 22 are formed. In the projected electrode 22 of the present embodiment, the diameter in the base portion, the diameter in the tip portion, and the height thereof are, for example, 40 μmφ, 30 μmφ, and 50 μm, respectively.

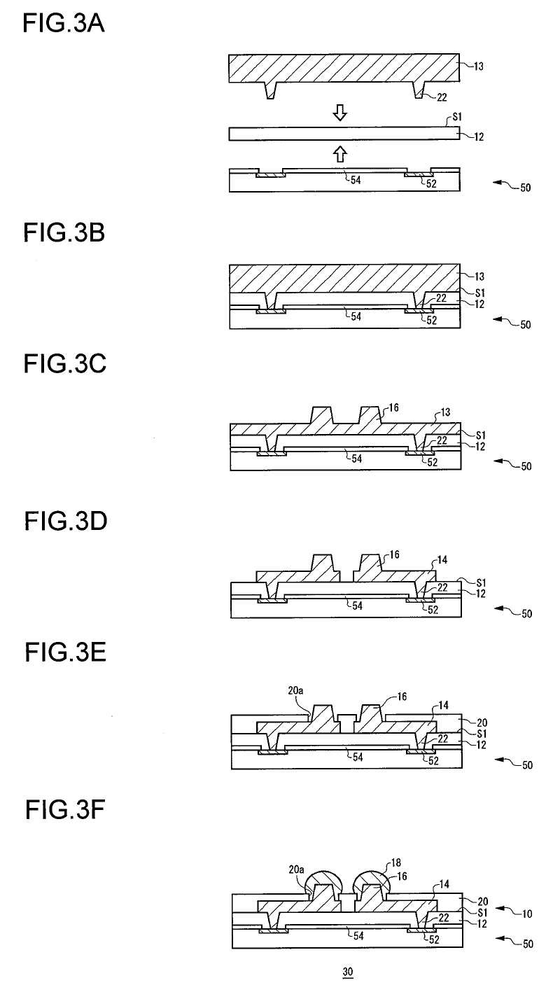

FIGS. 3A to 3F are cross-sectional diagrams illustrating a method for forming the wiring layer 14 and the low-melting metal ball 18, and a method for connecting the projected electrode 22 to the device electrode 52.

As illustrated in FIG. 3A, the copper plate 13 is arranged on one major surface S1 side of the insulating resin layer 12 such that the projected electrode 22 faces the insulating resin layer 12 side. The semiconductor device 50 in which the device electrode 52 facing the projected electrode 22 is provided, is arranged on the other major surface of the insulating resin layer 12. The thickness of the insulating resin layer 12 is about the height of the projected electrode 22, that is, about 35 μm. The copper plate 13 and the semiconductor device 50 are subsequently pressure-bonded via the insulating resin layer 12 by using a press machine. The pressure and temperature in the press working are about 5 Mpa and 180° C., respectively.

With the press working, the insulating resin layer 12 induces a plastic flow so that the projected electrode 22 penetrates the insulating resin layer 12. Then, as illustrated in FIG. 3B, the copper plate 13, the insulating resin layer 12, and the semiconductor device 50 are formed into one body such that the projected electrode 22 and the device electrode 52 are pressure-bonded, and the two are connected electrically. Because the projected electrode 22 has a shape in which the whole shape of the electrode becomes thinner as approaching the tip thereof, the projected electrode 22 smoothly penetrates the insulating resin layer 12. In the present embodiment, the copper plate 13 is pressure-bonded to the insulating resin layer 12 such that the copper plate 13 is stacked on one major surface S1 of the insulating resin layer 12.

As illustrated in FIG. 3C, resists (not illustrated) are formed selectively in accordance with the pattern of the projected portions 16 on the major surface of the copper plate 13 opposite to the insulating resin layer 12 by the lithography method. The major surface of the copper plate 13 is then etched by using the resists as a mask to form a certain pattern of the projected portions 16 on the copper plate 13. Subsequently, the resists are removed. In the projected portion 16 of the present embodiment, the diameter in the base portion, the diameter in the tip portion, and the height thereof are, for example, 150 μmφ, 100 μmφ, and 50 μm, respectively.

As illustrated in FIG. 3D, resists (not illustrated) are subsequently formed selectively in according with the pattern of the wiring layer 14 on the major surface of the copper plate 13 on the side where the projected portions 16 are formed, by the lithography method. The copper plate 13 is then etched by using the resists as a mask to be made into a certain pattern of the wiring layer 14. Subsequently, the resists are removed. In the wiring layer 14 of the present embodiment, the height thereof is about 20 μm.

Herein, after the formation of the wiring layer 14, certain concavities and convexities with, for example, an average roughness (Rz) of 10 points within the range of 0.5 to 3.0 μm, may also be formed. The concavities and convexities can be formed by, for example, performing a roughening treatment on the surface of the projected portions 16. Examples of the roughening treatment include, for example, a chemical treatment such as CZ treatment (registered trademark) and a plasma treatment or the like. In the case where the projected portions 16 are made of a rolled copper, the directions of the crystal grains of the copper forming the projected portions 16 are aligned in the direction parallel to the major surface of the wiring layer 14. Therefore, the concavities and convexities can be easily formed on the surface of the projected portions 16 by a roughening treatment performed on the surface of the projected portions 16. In addition, upon the roughening treatment of the projected portions 16, the wiring layer 14 may be simultaneously subjected to a roughening treatment. In this case, concavities and convexities are also formed on the side face of the wiring layer 14; hence, the connection strength between the protective layer 20, which will be formed in the following process, and the wiring layer 14 can be increased by an anchor effect.

As illustrated in FIG. 3E, the protective layer 20 in which the opening portions 20a are formed in the regions corresponding to the projected portions 16, is then formed on the major surface of the wiring layer 14 on the side where the projected portions 16 project by the lithography method, such that the projected portions 16 project from the opening portions 20a.

As illustrated in FIG. 3F, the low-melting metal balls 18 are then formed in the regions of the wiring layer 14 where the projected portions 16 are formed by using, for example, a solder printing method. Specifically, the low-melting metal balls 18 are formed by, for example, printing a solder paste in which a resin and a solder material are processed to a paste on desired positions with the use of a screen mask, and by heating the solder paste to the solder melting temperature. Alternatively, as another process, a flux may be applied to the side of the wiring layer 14 in advance, and the low-melting metal balls 18 may be mounted on the wiring layer 14. The low-melting metal ball 18 covers the whole surface of the projected portion 16 and part of the ball is engaged with the interior side face of the opening portion 20a. Due to this, the expansion of the low-melting metal ball 18 in the direction parallel to the major surface of the wiring layer 14 is prevented; hence, the ball height can be kept high. In the present embodiment, the diameter of the low-melting metal ball 18 in the direction parallel to the wiring layer 14 is about 160 to 250 μm, and the ball height thereof is about 140 μm in the state where the ball is mounted on the printed wiring board. The low-melting metal balls 18 may also be formed on the top face of the projected portions 16 by adjusting the opening portions of the screen mask.

By the production process described above, the semiconductor module 30 is formed. Or, when the semiconductor device 50 is not mounted, the substrate 10 for mounting a device is obtained.

As described above, in the substrate 10 for mounting a device according to the present embodiment, the projected portion 16 is integrally provided with the wiring layer 14. Due to this, even when a thermal stress occurs, there is less possibility that a crack could occur between the wiring layer 14 and the projected portion 16. Therefore, when the semiconductor module 30 in which the semiconductor device 50 is mounted on the substrate 10 for mounting a device, is implemented on a printed wiring board, the connection reliability between the semiconductor module 30 and the printed wiring board can be improved. Moreover, the connection reliability can be more improved due to the increase in the connection strength between the projected portion 16 and the low-melting metal ball 18 because of the formation of the concavities and convexities created on the surface of the projected portion 16.

Further, because the low-melting metal ball 18 is supported by the projected portion 16, the ball height can be kept high. In addition, because part of the low-melting metal ball 18 is engaged with the interior side face of the opening portion 20a such that the expansion of the low-melting metal ball 18 in the direction parallel to the major surface of the wiring layer 14 is prevented, the ball height can be kept higher. Because the ball height is kept high, the pitch between the electrodes of the semiconductor module 30, the electrodes being used for being implemented on a printed wiring board, can be made fine, and the implementation reliability is improved when the semiconductor module 30 with a structure in which the pitch between the electrodes is fined, is implemented on a printed wiring board.

### Embodiment 2

In the above Embodiment 1, the projected portion 16 is formed after the copper plate 13 and the semiconductor device 50 are subjected to pressure molding with the insulating resin layer 12 sandwiched between the two; however, the substrate 10 for mounting a device or a semiconductor module 30 may be formed in the following process. Hereinafter, the present embodiment will be described. It is noted that the projected electrode 22 is formed in the same way as with Embodiment 1, and the same structure as in Embodiment 1 is denoted with the same reference numeral as in Embodiment 1, and the description with respect thereto is omitted.

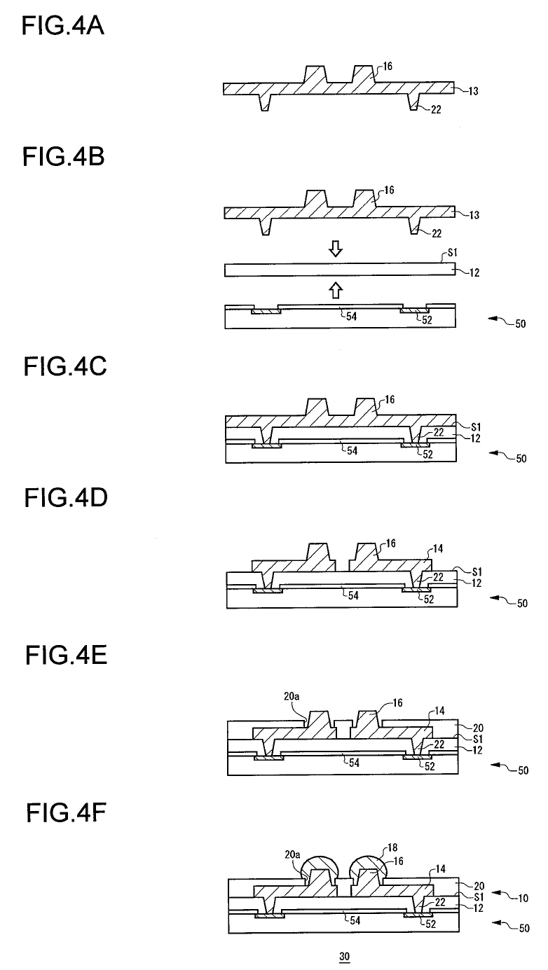

FIGS. 4A to 4F are diagrams illustrating a method for forming the wiring layer 14 and the low-melting metal ball 18, and a method for connecting the projected electrode 22 and the device electrode 52, in the present embodiment.

As illustrated in FIG. 4A, resists (not illustrated) are formed selectively in accordance with the pattern of the projected portions 16 on the major surface of the copper plate 13 on the opposite side to the side where the projected electrodes 22 are formed, by the lithography method. The major surface of the copper plate 13 is then etched by using the resists as a mask to form a certain pattern of the projected portions 16 on the copper plate 13. Subsequently, the resists are removed. Herein, after the formation of the projected portions 16, certain concavities and convexities may also be formed on the surface of the projected portion 16 in the same way as with Embodiment 1. In addition, the projected electrodes 22 may be simultaneously subjected to a roughening treatment. In this case, concavities and convexities are also formed on the side face of the projected electrodes 22; hence, the connection strength between the insulating resin layer 12 and the projected electrode 22 can be increased by an anchor effect.

As illustrated in FIG. 4B, the copper plate 13 and the semiconductor device 50 are then pressure-bonded via the insulating resin layer 12, in the same way as with Embodiment 1. As a result, the copper plate 13, the insulating resin layer 12, and the semiconductor device 50 are formed into one body, and the projected electrode 22 penetrates the insulating resin layer 12 such that the projected electrode 22 and the device electrode 52 are connected electrically, as illustrated in FIG. 4C.

As illustrated in FIG. 4D, resists (not illustrated) are formed selectively in accordance with the pattern of the wiring layer 14 on the major surface of the copper plate 13 on the side where the projected portions 16 are formed by the lithography method. The copper plate 13 is then etched by using the resists as a mask to be made into the wiring layer 14. Subsequently, the resists are removed.

As illustrated in FIG. 4E, the protective layer 20 is then formed on the major surface of the wiring layer 14 on the side where the projected portions 16 project, in the same way as with Embodiment 1.

As illustrated in FIG. 4F, the low-melting metal balls 18 are then formed in the regions of the wiring layer 14 where the projected portions 16 are formed, in the same way as with Embodiment 1.

By the production process described above, the semiconductor device 30 is formed. Or, when the semiconductor device 50 is not mounted, the substrate 10 for mounting a device can be obtained.

According to the present embodiment, the following advantages can be further obtained in addition to the above effects of Embodiment 1. That is, in the present embodiment, the copper plate 13 and the semiconductor device 50 are pressure-bonded via the insulating resin layer 12 after the formation of the projected portions 16. Therefore, the projected portions 16 can be formed at a same time when a positioning alignment mark used when the copper plate 13 is pressure-bonded to the insulating resin layer 12, is formed on the copper plate 13. Due to this, an increase in the number of the production processes when the projected portions 16 are formed, can be prevented, leading to the prevention of an increase in the production cost. Or, the projected portion 16 itself can be used as an alignment mark. Moreover, because the copper plate 13, which becomes thin in its thickness due to the formation of the projected portions 16, can be pressure-bonded to the insulating resin layer 12, the peeling between the copper plate 13 and the insulating resin layer 12 resulting from the difference between the coefficients of thermal expansion of the two, can be prevented.

### Embodiment 3

A portable apparatus provided with the semiconductor module of the present invention will be described below. An example will be taken in which the semiconductor module is mounted on a portable phone as the portable apparatus; however, the portable apparatus may also be an electronic apparatus such as, for example, a personal digital assistance (PDA), a digital camcorder (DVC), and a digital still camera (DSC).

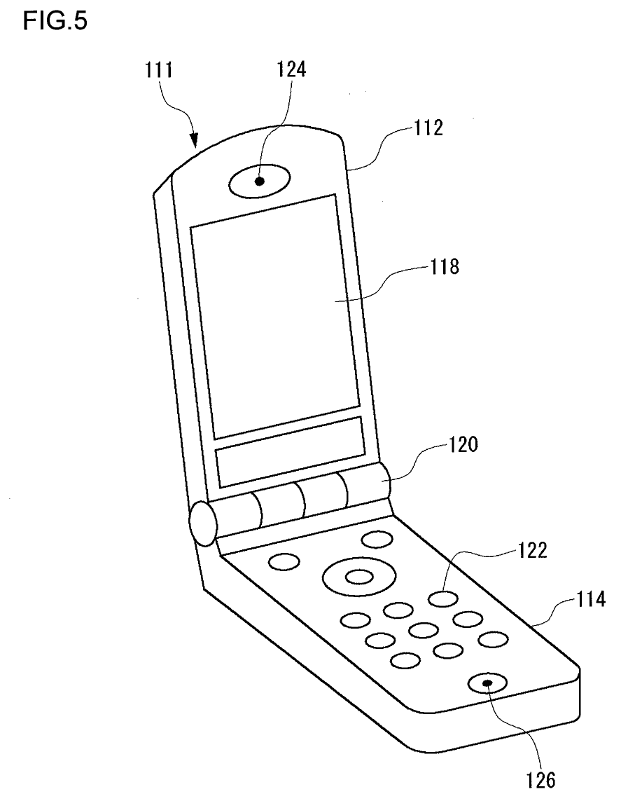

FIG. 5 is a diagram illustrating the structure of a portable phone provided with the semiconductor module 30 according to the present invention. The portable phone 111 has a structure in which the first case 112 and the second case 114 are connected by the movable portion 120. The first case 112 and the second case 114 are pivoted on the movable portion 120. On the first case 112, the display unit 118 displaying information such as characters and images or the like, and the speaker unit 124 are provided. On the second case 114, the manipulation unit 122 such as manipulation buttons or the like, and the microphone unit 126 are provided. The semiconductor module 30 directed to each embodiment of the present invention is mounted inside such portable phone 111.

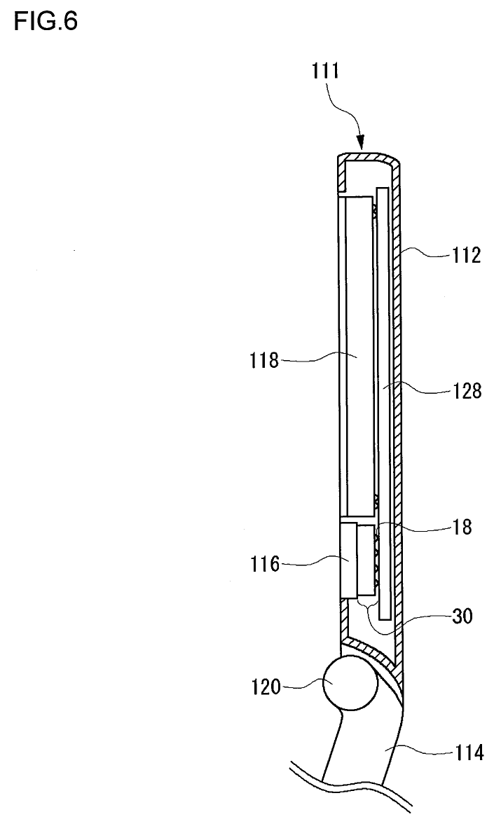

FIG. 6 is a partial cross-sectional diagram of the portable phone illustrated in FIG. 5 (cross-sectional diagram of the first case 112). The semiconductor module 30 directed to each embodiment of the present invention is mounted on the printed wiring board 128 via the low-melting metal ball 18 to be connected electrically to the display unit 118 or the like via such printed wiring board 128. A heat-dissipating substrate 116 such as a metal substrate is provided on the back face side of the semiconductor module 30 (on the face opposite to the low-melting metal ball 18) such that, for example, the heat generated by the semiconductor module 30 is efficiently dissipated toward the outside of the first case 112 without persisting therein.

According to the semiconductor module 30 directed to each embodiment of the present invention, the connection reliability between the semiconductor module 30 and a printed wiring board can be improved; hence, the reliability with respect to the portable apparatus directed to the present embodiment in which such semiconductor module 30 is mounted, can be improved.

The present invention should not be limited to each of the above embodiments, and various modifications, such as design modifications, may be made based on knowledge of a person skilled in the art. Embodiments in which such modifications are added should also fall within the scope of the present invention.

For example, in each embodiment stated above, the wiring layer is a single layer, but may also be multiple layers without being limited thereto.

In each embodiment stated above, the low-melting metal ball is taken as an example of a connection metal in the present application, but the shape thereof should not be limited to a ball shape. In addition, the height thereof is referred to as the “ball height” for convenience, the shape similarly should not be limited to a ball shape.

Moreover, the structure of the present invention can be applied to the production process of semiconductor packages referred to as the “Wafer Level CSP (Chip Size Package) Process”. With the process, semiconductor modules can be made thinner and be miniaturized.

What is claimed is:

1. A substrate for mounting a device comprising:
an insulating resin layer;
a wiring layer provided on one major surface of the insulating resin layer; and
a projected portion that projects toward the direction opposite to the insulating resin layer from the wiring layer, and that is used for supporting a connection metal, while being connected to the wiring layer electrically, wherein the projected portion is integrally provided with the wiring layer.

2. The substrate for mounting a device according to claim 1, wherein the connection metal is provided in a region of the wiring layer where the projected portion projects.

3. The substrate for mounting a device according to claim 1, wherein the connection metal covers the whole surface of the projected portion.

4. The substrate for mounting a device according to claim 1, wherein concavities and convexities are formed on the surface of the projected portion.

5. The substrate for mounting a device according to claim 4, wherein an average roughness (Rz) of 10 points of the concavities and convexities is within the range of 0.5 to 3.0 μm.

6. The substrate for mounting a device according to claim 1, wherein the wiring layer and the projected portion are made of a rolled metal.

7. The substrate for mounting a device according to claim 1, wherein the side face of the projected portion has a tapered shape with a progressively smaller diameter toward the top of the projected portion from the major surface of the wiring layer.

8. The substrate for mounting a device according to claim 2 further comprising a protective layer that has an opening portion formed in a region corresponding to the projected portion, and that is provided on the major surface of the wiring layer on the side where the projected portion projects such that the projected portion projects from the opening portion, wherein part of the connection metal is engaged with the interior side face of the opening portion.

9. The substrate for mounting a device according to claim 2, wherein the connection metal is formed on the top face of the projected portion.

10. A semiconductor module comprising:
the substrate for mounting a device according to claim 1; and
a semiconductor device mounted on the substrate for mounting a device.

11. The semiconductor module according to claim 10, wherein the substrate for mounting a device comprises a projected electrode that is connected to the wiring layer electrically and projects toward the insulating resin layer side from the wiring layer, and wherein the semiconductor device comprises a device electrode facing the projected electrode, and wherein the projected electrode penetrates the insulating resin layer to be connected to the device electrode electrically.

12. A portable apparatus in which the semiconductor module according to claim 10 is mounted.
